(19) United States
(12) Patent Application Publication
(10) Pub. No.: US 2023/0391219 A1
(43) Pub. Date: Dec. 7, 2023

(54) METHOD AND DEVICE FOR MANAGING POWER OF ELECTRIC VEHICLE CHARGING STATION USING ESS

(71) Applicant: AEONUS CO., LTD, Suwon-si (KR)

(72) Inventor: Eun HEO, Yongin-si (KR)

(21) Appl. No.: 18/249,960

(22) PCT Filed: Jun. 7, 2021
(86) PCT No.: PCT/KR2021/007077

§ 371 Date: Apr. 20, 2023

(30) Foreign Application Priority Data
Oct. 22, 2020 (KR) 10-2020-0137372

(51) Int. Cl. B60L 53/62; B60L 53/10; B60L 55/00; B60L 58/12; B60L 58/16

(52) U.S. Cl. CPC B60L 53/62; B60L 53/11; B60L 58/16; B60L 58/12; B60L 55/00

(57) ABSTRACT

The present embodiment provides a method and device for managing the power of an electric vehicle charging station by using an ESS. More specifically, provided are a method and device for controlling to set the ESS to a discharge mode and supply power to a plurality of high-speed chargers connected to the ESS, thereby enabling high-speed charging through the plurality of high-speed chargers, when it is determined that the charging amount of the ESS is greater than a first set value, and controlling to set the ESS to a charge mode and not supply power to the plurality of high-speed chargers, thereby stopping the operation of the plurality of high-speed chargers, when it is determined that the charging amount of the ESS is smaller than the first set value.

### TECHNICAL FIELD

The present invention relates to relate to a technology for managing charging and discharging of power by using an energy storage system (ESS).

### BACKGROUND ART

In general, vehicles use gasoline or diesel as fuel, gasoline or diesel generates harmful gas during combustion so as to cause air pollution. Moreover, since there is little crude oil for making gasoline or diesel left on the earth, alternative energy is being developed in various industrial fields, and an electric vehicle is spotlighted as a solution for vehicles.

With proliferation of electric vehicles, the demand for charging is increasing, so a charging infrastructure expansion is required. Chargers for charging such electric vehicles may be classified into a low-speed charger and a high-speed charger.

In a case in which the low-speed charger which slowly charges for a long time is used, power is supplied through a distribution network to prevent emergence of problems in terms of power management. However, in a case in which the high-speed charger which quickly charges in a short time is used, power stored in an ESS is supplied, and thus, problems in terms of power management occur.

Therefore, as the power stored in the ESS is supplied to the high-speed charger while being managed in consideration of the state of charge and the state of health (SOH) of the ESS, a demand for a power management method of controlling the operation of the high-speed charger is increasing.

### DISCLOSURE

### Technical Problem

According to an embodiment, it is an object of the present invention to provide a method and a device of controlling in such a way that, if it is determined that the charging amount of an energy storage system (ESS) is greater than a first set value, the ESS is set to a discharge mode and power is supplied to the ESS from multiple high-speed chargers connected to the ESS so as to achieve high-speed charging through the multiple high-speed chargers, and if the charging amount of the ESS is determined to be less than the first set value, the ESS is set to a charge mode and power is not supplied to the plural high-speed chargers so as to stop the operation of the multiple high-speed chargers.

According to an embodiment, it is an object of the present invention to provide a method and a device of controlling in such a way that, if it is determined that the charging amount of an energy storage system (ESS) is greater than a second set value, power is supplied to high-speed chargers which are in operation so as to continue the high-speed charging through the high-speed chargers in operation, in a case in which the high-speed charging through the high-speed chargers in operation is continued, when the high-speed charging through the high-speed chargers in operation is completed, the ESS is set to a charge mode so that the operation of the high-speed chargers in operation is stopped, and if it is determined that the charging amount of the ESS is smaller than the second set value, even if the high-speed charging through the high-speed chargers in operation is not completed, the ESS is set to the charge mode so that the operation of the high-speed chargers in operation is stopped.

The foregoing and other objects and advantages of the present invention will become apparent from the following description of the preferred embodiments.

### Technical Solution

To accomplish the above-mentioned objects, according to the present invention, there is provided a method of managing power of an electric vehicle charging station by using an energy storage system (ESS) in a power management device, including the steps of: measuring the charging amount of the ESS by checking the state of charge (SOC) of the ESS; determining whether the charging amount of the ESS is less than a first set value set through the emergency storage capacity of the ESS; if it is determined that the charging amount of the ESS is greater than the first set value, setting the ESS to a discharge mode, and controlling the ESS to enable high-speed charging through a plurality of high-speed chargers connected to the ESS by providing power to the plurality of high-speed chargers; if it is determined that the charging amount of the ESS is less than the first set value, setting the ESS to a charge mode, and controlling the ESS to stop the operation of the plurality of high-speed chargers by not supplying power to the plurality of high-speed chargers; in a case in which the ESS is set to the discharge mode, simultaneously operating the high-speed chargers that exceed a reference value, among the plurality of high-speed chargers, and checking the charging state of the ESS again when the discharging amount of the ESS reaches a target value; and in a case in which the ESS is set to the charge mode, checking the charging state of the ESS again if the charge mode of the ESS is maintained for a predetermined reference period.

The method of managing power of an electric vehicle charging station further includes the steps of: if it is determined that the charging amount of the ESS is less than the first set value, determining whether there is a high-speed charger in operation which provides a high-speed charge service, among the plurality of high-speed chargers; if it is determined that there is no high-speed charger in operation, setting the ESS to the charge mode, and controlling to stop the operation of the plurality of high-speed chargers; if it is determined that there is a high-speed charger in operation, determining whether the charging amount of the ESS is less than the second set value based on the state of health (SOH) of the ESS; if it is determined that the charging amount of the ESS is greater than the second set value, controlling to supply power to the high-speed charger in operation to continue high-speed charging through the high-speed charger in operation; if the high-speed charging through the high-speed charger in operation is continued, when the high-speed charging is completed, setting the ESS to the charging mode and controlling to stop the operation of the high-speed charger in operation; and if it is determined that the charging amount of the ESS is less than the second set value, setting the ESS to the charging mode and controlling to stop the operation of the high-speed charger in operation even if high-speed charging through the high-speed charger in operation is not completed.

The method of managing power of an electric vehicle charging station further includes the steps of: if the frequency of a grid network exceeds a predetermined reference value, receiving a first command from an upper controller that manages a plurality of power management devices arranged in different regions, and setting the ESS to the charging mode according to the first command; if the frequency of a grid network is lower than the reference value, receiving a second command from an upper controller, and setting the ESS to the discharging mode according to the second command; detecting the frequency of a distribution network connected to the ESS, and if it is determined that the frequency of the distribution network is higher than a reference range, setting the ESS to the charging mode, and if it is determined that the frequency of the distribution network is lower than a reference range, setting the ESS to the discharging mode; if the ESS is connected to a vehicle to grid (V2G) device, controlling power not to be supplied from the V2G device to the grid network, and controlling the power supplied from the V2G device to be first stored in the ESS or to be used as power consumption in a charging station; and when a third command is received from the upper controller, controlling power to be supplied from the V2G device to the grid network according to the third command.

The method of managing power of an electric vehicle charging station further includes the steps of: measuring a first usage for each of the plurality of high-speed chargers installed in the electric vehicle charging station during a predetermined period; measuring a second usage for each of the plurality of low-speed chargers installed in the electric vehicle charging station during the predetermined period; obtaining a plan view of the electric vehicle charging station, first moving line data of electric vehicles that visited the electric vehicle charging station for high-speed charging during the predetermined period, and second moving line data of electric vehicles that visited the electric vehicle charging station for low-speed charging during the predetermined period; and applying the plan view, the first moving line data, the second moving line data, the first usage, and the second usage to an artificial neural network to select positions where the plurality of high-speed chargers and low-speed chargers will be rearranged, based on the output of the artificial neural network.

The plan view includes an entrance and an exit of the electric vehicle charging station, and the starting point of the first and second moving line data coincide with the entrance of the electric vehicle charging station and the end point of the first and second moving line data coincide with the exit of the electric vehicle charging station. The relocation of each of the plurality of high-speed chargers may be made on the basis of the output of the artificial neural network trained according to reinforcement learning, so that the plurality of high-speed chargers are positioned at regular intervals from the start point to the end point of the first moving line data while changing the position of the high-speed charger for which the first usage is classified as being used more by exceeding the reference range, and the position of the high-speed charger for which the first usage is classified as being used less by falling short of the reference range. The relocation of each of the plurality of low-speed chargers may be made on the basis of the output of the artificial neural network trained according to reinforcement learning, so that the plurality of low-speed chargers are positioned at regular intervals from the start point to the end point of the second moving line data while changing the position of the low-speed charger for which the second usage is classified as being used more by exceeding the reference range, and the position of the low-speed charger for which the second usage is classified as being used less by falling short of the reference range.

The artificial neural network may provide more a first compensation as the positions of the over-used high-speed chargers are rearranged to be close to the end point of the first moving line data in high use order of the first usage, provide more a second compensation as the positions of the high-speed chargers, which are used less, are rearranged to be close to the starting point of the first moving line data in low use order of the first usage, provide a third as the positions of the over-used low-speed chargers are rearranged to be close to the end point of the second moving line data in high use order of the second usage, and provide a fourth compensation as the positions of the low-speed chargers, which are used less, are rearranged to be close to the starting point of the second moving line data in low use order of the second usage.

### Advantageous Effects

According to an embodiment, the present invention can control to prevent power from being supplied from the ESS to the plural high-speed chargers when the charging amount of the ESS falls below the first set value since power stored in the ESS is needed in order to use the plural high-speed chargers, thereby stopping the high-speed charging service through the plurality of high-speed chargers.

In addition, according to an embodiment, in a case in which high-speed charging through the high-speed chargers in operation is needed, since the high-speed charger is connected with an electric vehicle to provide a high-speed charging service, so the high-speed charging cannot be stopped abruptly. Accordingly, the present invention can maintain the high-speed charging until the charging amount falls below the second set value which is a value to influence on the lifespan of the ESS. Furthermore, the present invention can change the ESS into the charge mode in order to increase the charging amount of the ESS without restarting the high-speed charging when the high-speed charging through the high-speed chargers in operation is completely.

The effects of the present invention are not limited to the above-mentioned effects and further effects not described above will be clearly understood by those skilled in the art.

### DESCRIPTION OF DRAWINGS

FIG. 1 is a diagram schematically illustrating a configuration of a system for providing a method of managing power of an electric charging station according to an embodiment.

FIG. 2 is a flow chart illustrating a process of setting a charge mode and a discharge mode of an ESS according to an embodiment.

FIG. 3 is a flow chart illustrating a process of controlling the operation of high-speed chargers in operation according to an embodiment.

FIG. 4 is a flow chart illustrating a process of setting a charge mode and a discharge mode of the ESS according to a command received from a high-rank controller according to an embodiment.

FIG. 5 is a flow chart illustrating a process of setting a charge mode and a discharge mode of the ESS through a frequency of a distribution network according to an embodiment.

FIG. 6 is a flow chart illustrating a process of controlling power to be supplied from a V2G device to a grid system according to a command received from a high-rank controller according to an embodiment.

FIG. 7 is a diagram illustrating a process of controlling power supply through an ATS according to an embodiment.

FIG. 8 is a flow chart illustrating a process of selecting relocation positions of a high-speed charger and a low-speed charger according to an embodiment.

FIG. 9 is a diagram for depicting training of an artificial neural network according to an embodiment.

### MODE FOR INVENTION

Hereinafter, the present invention will be described in detail with reference to the embodiments of the present invention and the drawings. It will be apparent to those of ordinary skill in the art that these embodiments are merely illustrative to describe the present invention in more detail, and the scope of the present disclosure is not limited by these embodiments. It should be understood that the embodiments of the present disclosure include all modifications, equivalents, or replacements included in the spirit and technical scope of the present disclosure.

The structural or functional descriptions of the embodiments are illustrated for the purpose of describing an embodiment according to the concept of the present disclosure, and embodiments according to the concept of the present disclosure may be realized in various forms. Therefore, it should be understood that the embodiments of the present disclosure are not intended to be limited as a specific form, and the scope of the present invention includes all modifications, equivalents, and replacements included in the spirit and technical scope of the present disclosure.

Terms such as first or second may be used to describe various components, but the components are not limited to the terms. The terms are only for the purpose of distinguishing one component from other components, for example, without departing from the scope of the present disclosure, a first component may be referred to as a second component, and similarly, a second component may also be referred to as a first component.

It should be understood that when a component is referred to as being “connected” to another component, it may be directly connected or coupled to the other component, but it should be understood that there may be other components therebetween.

The terms used in the following description are intended to merely describe specific embodiments, but not intended to limit the invention. An expression of the singular number includes an expression of the plural number, so long as it is clearly read differently. The terms such as “include” or “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

Unless otherwise defined, it will be understood that all terms used in the specification including technical or scientific terms has the same meanings as to be generally or commonly understood by those of ordinary skill in the art. It will be further understood that words or terms described as the meaning defined in commonly used dictionaries shall be interpreted as having meanings that are consistent with their meanings in the context of the relevant art and the technical idea of the invention, and shall not be interpreted as having ideal meanings or excessively formal meanings, not otherwise particularly stated.

In the following description of the accompanying drawings, like reference numerals refer to like elements regardless of the reference numerals, and redundant descriptions thereof will be omitted. In describing the embodiment, when it is determined that the detailed description of the relevant known art may unnecessarily obscure the gist of the embodiment, the detailed description thereof will be omitted.

Embodiments may be realized as various types of products such as a personal computer, a laptop computer, a tablet computer, a smartphone, a television set, a smart home appliance, an intelligent vehicle, a kiosk, a wearable device, and the like.

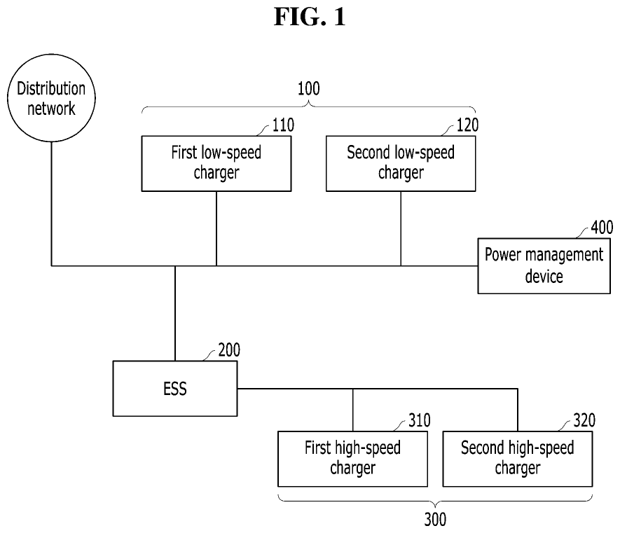

FIG. 1 is a diagram schematically illustrating a configuration of a system for providing a method of managing power of an electric vehicle charging station according to an embodiment.

Referring to FIG. 1, a system according to an embodiment may include a plurality of low-speed chargers 100, an ESS 200, a plurality of high-speed chargers 300, and a power management device 400.

The plurality of low-speed chargers 100 may include a first low-speed charger 110, a second low-speed charger 120, and the like, and may be directly connected to a distribution network to provide a low-speed charging service to an electric vehicle.

The ESS 200 may be connected to the distribution network through a low voltage panel, may charge and store the power supplied from the distribution network, and may discharge the charged power to be supplied to the plurality of high-speed chargers 300.

The plurality of high-speed chargers 300 may include a first high-speed charger 310, a second high-speed charger 320, and the like, and may be connected to the ESS 200 to provide a high-speed charging service to the electric vehicle.

The power management device 400 may control operations of the plurality of low-speed chargers 100, the ESS 200, the plurality of high-speed chargers 300, and the like.

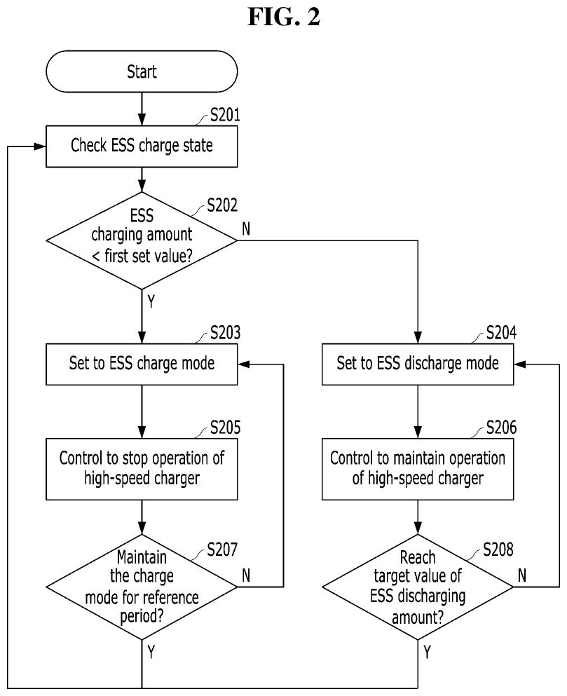

The power management device 400 includes a processor and a memory. The processor of the power management device 400 may perform at least one method described below with reference to FIGS. 2 to 9. The memory of the power management device 400 may store information related to methods described below or may store a program in which methods described below are implemented. The memory of the power management device 400 may be a volatile memory or a non-volatile memory.

The processor of the power management device 400 may execute a program and control the power management device 400. Codes of the program executed by the processor of the power management device 400 may be stored in the memory of the power management device 400.

The power management device 400 may be connected to an external device (e.g., a personal computer or a network) through an input/output device (not shown), and may exchange data with an external device through wired/wireless communication.

The power management device 400 may be used to train an artificial neural network. The memory of the power management device 400 may include a trained artificial neural network. The processor of the power management device 400 may execute an artificial neural network algorithm stored in the memory of the power management device 400. The power management device 400 for training the artificial neural network and the power management device 400 using the trained artificial neural network may be the same or different from each other.

FIG. 2 is a flow chart illustrating a process of setting a charge mode and a discharge mode of the ESS according to an embodiment.

First, in step S201, the power management device 400 may check the state of charge (SOC) of the ESS 200 to measure the charging amount of the ESS 200.

In step S202, the power management device 400 may determine whether the charging amount of the ESS 200 is smaller than the first set value.

The first set value according to an embodiment may be set through an emergency storage amount of the ESS 200, and for example, in a case in which the minimum emergency storage amount to be stored for use in an emergency due to a power outage is 10 Wh, the first set value may be set to 10 Wh.

In step S202, in a case in which it is determined that the charging amount of the ESS 200 is less than the first set value, in step S203, the power management device 400 may set the ESS 200 to the charge mode.

In step S202, in a case in which it is determined that the charging amount of the ESS 200 is larger than the first set value, in step S204, the power management device 400 may set the ESS 200 to the discharge mode.

In a case in which the ESS 200 is set to the charge mode, in step S205, the power management device 400 may control power not to be supplied from the ESS 200 to the plurality of high-speed chargers 300, thereby stopping the operation of the plurality of high-speed chargers 300.

When the ESS 200 is set to the discharge mode, in step S206, the power management device 400 may control power to be supplied from the ESS 200 to the plurality of high-speed chargers 300, so that the plurality of high-speed chargers 300 may operate to perform high-speed charging.

According to an embodiment, in the case in which the ESS 200 is set to the charge mode, the power management device 400 may check again the state of charge of the ESS 200 when the charge mode of the ESS 200 is maintained for a predetermined reference period.

Specifically, in step S207, the power management device 400 may determine whether the charge mode has been maintained for the predetermined reference period.

In step S207, in a case in which it is determined that the charge mode has been maintained for the reference period, the power management device 400 may return to step S201, and check again the state of charge of the ESS 200.

In step S207, in a case in which it is determined that the charge mode has not been maintained for the reference period, the power management device 400 may return to step S203, and can be set to maintain the charge mode of the ESS 200.

According to an embodiment, in a case in which the ESS 200 is set to the discharge mode, the high-speed chargers of which charging amount is more than the reference value, among the plurality of high-speed chargers, are operated at the same time, and the power management device 400 may check the state of charge of the ESS 200 again when the discharging amount of the ESS 200 reaches a target value.

Specifically, in step S208, the power management device 400 may determine whether the discharging amount of the ESS 200 reaches the target value by increasing the discharging amount of the ESS 200 as the high-speed chargers of which charging amount is more than the reference value, among the plurality of high-speed chargers, are operated at the same time.

In step S208, if it is determined that the discharging amount of the ESS 200 reaches the target value, the power management device 400 may return to step S201, and may check again the state of charge of the ESS 200.

In step S208, if it is determined that the discharging amount of the ESS 200 does not reach the target value, the power management device 400 may return to step S204, and may set the discharge mode of the ESS 200 to be maintained.

As described above, according to an embodiment, since power stored in the ESS 200 is required to use the plurality of high-speed chargers 300, if the charging amount of the ESS 200 falls below the first set value, the power management device 400 may control in such a way that power is not supplied to the plurality of high-speed chargers 300 from the ESS 200 to stop the high-speed charging service through the plurality of high-speed chargers 300.

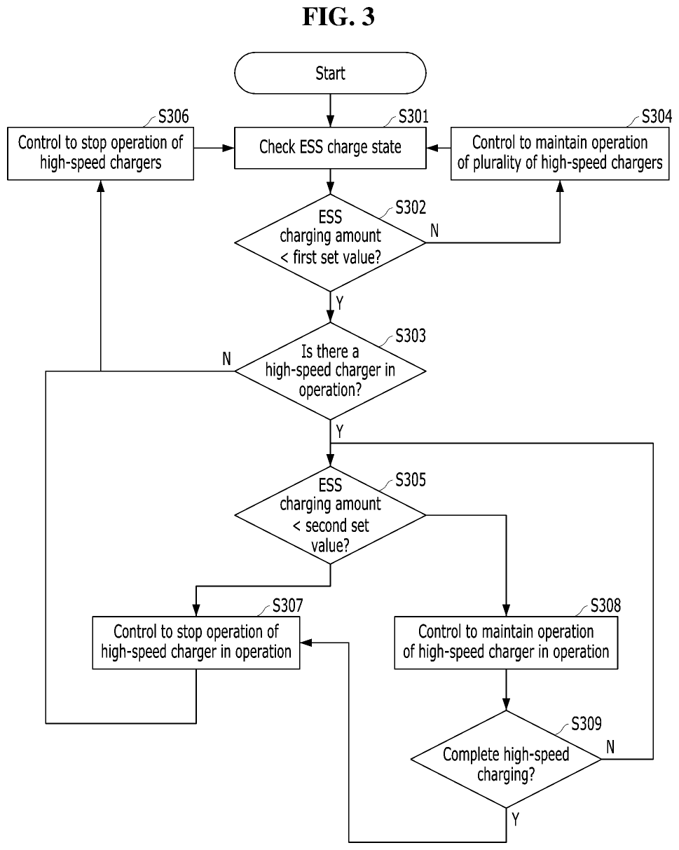

FIG. 3 is a flow chart illustrating a process of controlling the operation of high-speed chargers according to an embodiment.

First, in step S301, the power management device 400 may check the state of charge of the ESS 200 to measure the charging amount of the ESS 200.

In step S302, the power management device 400 may determine whether the charging amount of the ESS 200 is smaller than the first set value.

In step S302, if it is determined that the charging amount of the ESS 200 is less than the first set value, in step S303, the power management device 400 may determine whether there is a high-speed charger in operation, which is providing a high-speed charging service, among the plurality of high-speed chargers 300.

For example, in a case in which an electric vehicle is connected to the first high-speed charger 310 and the first high-speed charger 310 is currently providing the high-speed charging service, the power management device 400 may determine that there is a high-speed charger in operation by grasping the first high-speed charger 310 as a high-speed charger in operation.

In step S302, if it is determined that the charging amount of the ESS 200 is larger than the first set value, in step S304, the power management device 400 may set the ESS 200 to the discharge mode and control to maintain the operation of the plurality of high-speed chargers 300.

After the step S304, the power management device 400 may return to step S301, and check again the state of charge of the ESS 200.

Meanwhile, in step S303, if it is determined that there is a high-speed charger in operation, in step S305, the power management device 400 may determine whether the charging amount of the ESS 200 is smaller than the second set value.

The second set value according to an embodiment may be set through the state of health (SOH) of the ESS 200 and set to a value lower than the first set value. For example, in a case in which the first set value is 10 Wh and a value starting to affect the lifespan of the ESS 200 is 5 Wh, the second set value may be set to 5 Wh.

In step S303, if it is determined that there is no high-speed charger in operation, in step S306, the power management device 400 may set the ESS 200 to be in the charge mode and control to stop the operation of the plurality of high-speed chargers 300.

After the step S306, the power management device 400 may return to step S301, and check again the state of charge of the ESS 200.

Meanwhile, in step S305, if it is determined that the charging amount of the ESS 200 is less than the second set value, in operation S307, the power management device 400 may set the ESS 200 to be in the charge mode even if the high-speed charging through the high-speed charger in operation is not completed, and control to stop the operation of the high-speed charger in operation.

In step S305, if it is determined that the charging amount of the ESS 200 is greater than the second set value, in step S308, the power management device 400 may supply power to the high-speed charger in operation and control to continue the high-speed charging through the high-speed charger in operation. In this case, the power management device 400 may control such that power is supplied only to the high-speed charger currently performing the high-speed charger service, among the plurality of high-speed chargers 300, and control such that power is not supplied to the other high-speed chargers, so that there is no additional high-speed charging.

In a case in which high-speed charging is continued through the high-speed charger in operation, in step S309, the power management device 400 may determine whether high-speed charging is completed through the high-speed charger in operation.

In step S309, if it is determined that the high-speed charging is completed, in step S307, the power management device 400 may set the ESS 200 to be in the charge mode and control to stop the operation of the high-speed charger in operation.

In step S309, if it is determined that the high-speed charging is not completed, the power management device 400 may return to step S305, and determine again whether the charging amount of the ESS 200 is smaller than the second set value.

In step S307, in a case in which the operation of the high-speed charger in operation is stopped, the overall operation of the plurality of high-speed chargers 300 is stopped, and thus in operation S306, the power management device 400 may control to stop the plurality of high-speed chargers 300.

As described above, according to an embodiment, the high-speed chargers cannot suddenly stop the high-speed charging service since providing the high-speed charging service by being connected to the electric vehicle at the time of high-speed charging through the high-speed charger in operation. Accordingly, the high-speed chargers may maintain the high-speed charging until the charging amount falls below the second set value which has an influence on the lifespan of the ESS 200. When the high-speed charging is completed through the high-speed chargers in operation, the ESS 200 may be changed to the charge mode in order to increase the charging amount of the ESS 200 without restarting high-speed charging.

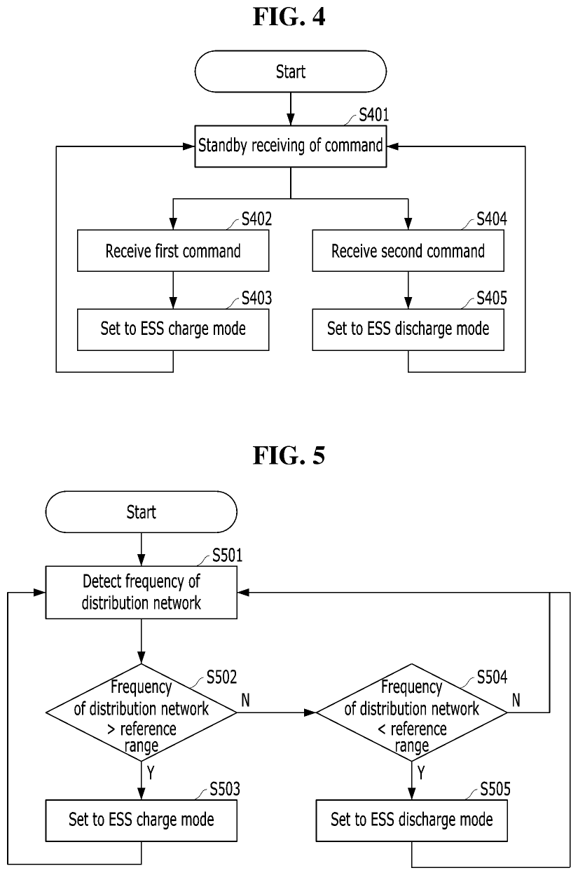

FIG. 4 is a flow chart illustrating a process of setting a charge mode and a discharge mode of the ESS according to a command received from a upper controller according to an embodiment.

According to an embodiment, a plurality of power management devices 400 may be arranged for each region, and the plurality of power management devices 400 may be connected to the upper controller through an internet network.

The upper controller is a device for managing the plurality of power management devices 400 arranged for each region, and may transmit a command to each of the plurality of power management devices 400 in order to control each of the plurality of power management devices 400.

For example, the power management device 400 can recognize only data in the region in which the power management device 400 is arranged, so can be operated only on the spot. The upper controller can control it remotely.

In step S401, the power management device 400 may maintain a standby state for receiving a command from an upper controller.

In a case in which the frequency of the grid network is higher than the reference value, when a command of an operator operating the distribution system is input, the upper controller may transmit a first command, which is an operation execution command for stabilizing the grid network when the frequency of the grid network is high, to the power management device 400. In step S402, the power management device 400 may receive the first command from the upper controller.

In step S403, the power management device 400 may set the ESS 200 to be in the charge mode according to the first command, and control the power supplied through the grid network to be stored in the ESS 200, thereby performing an operation for stabilizing the grid network when the frequency of the grid network is high.

In a case in which the frequency of the grid network is lower than the frequency of the grid network is lower than the reference value, when a command of an operator operating the distribution system is input, the upper controller may transmit a second command, which is an operation execution command for stabilizing the grid network when the frequency of the grid network is low, to the power management device 400. In step S404, the power management device 400 may receive the second command from the upper controller.

In step S405, the power management device 400 may set the ESS 200 to be in the discharge mode according to the second command and control to supply the power stored in the ESS 200 to the grid network, thereby performing an operation for stabilizing the grid network when the frequency of the grid network is low.

After the step S403 and the step S405, the power management device 400 may return to step S401, and maintain the standby state for receiving the command from the upper controller again.

FIG. 5 is a flow chart illustrating a process of setting the charge mode and the discharge mode of the ESS through the frequency of the distribution network according to an embodiment.

First, in step S501, the power management device 400 may detect the frequency of the distribution network connected to the ESS 200.

In step S502, the power management device 400 may determine whether the frequency of the distribution network is higher than a reference range.

In step S502, if it is determined that the frequency of the distribution network is out of the reference range, in step S503, the power management device 400 may set the ESS 200 to be in the charge mode.

In step S502, if it is determined that the frequency of the distribution network is not higher than the reference range, in step S504, the power management device 400 may determine whether the frequency of the distribution network is lower than the reference range.

In step S504, if it is determined that the frequency of the distribution network is lower than the reference range, in step S505, the power management device 400 may set the ESS 200 to be in the discharge mode.

In step S504, if it is confirmed that the frequency of the distribution network is not out of the reference range, since the frequency of the distribution network is within the reference range, the power management device 400 may return to step S501, and re-detect the frequency of the distribution network connected to the ESS 200.

In addition, after steps S503 and S505, returning to step S501, the power management device 400 may re-detect the frequency of the distribution network connected to the ESS 200.

As described above, the power management device 400 may autonomously detect the frequency in the distribution network of the restricted area and actively control the ESS 200 to be charged and discharged.

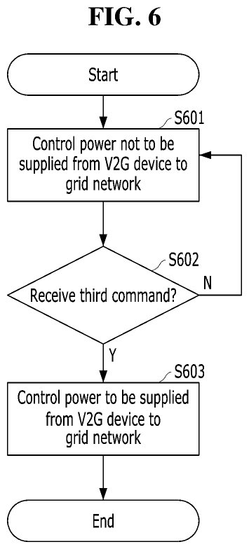

FIG. 6 is a flow chart illustrating a process of controlling power to be supplied from a vehicle to grid (V2G) device to a grid network according to a command received from the upper controller according to an embodiment.

First, in step S601, in a case in which the ESS 200 and the V2G device are connected to each other, the power management device 400 may control power not to be supplied from the V2G device.

That is, the power management device 400 may control power not to be directly supplied from the V2G device so that the power supplied from the V2G device is first stored in the ESS 200 or is used for consumption in the station.

According to an embodiment, the V2G device is a device for charging an electric vehicle through the power network and then transmitting the electricity remaining after the driving to the power network, and may serve as an ESS to move the electric vehicle connected to the V2G device.

According to an embodiment, the power consumption in the station is basically consumed by auxiliary facilities in a generator, and may include power consumed when a generator and a transformer lose power or stop operation.

In step S602, the power management device 400 may determine whether a third command is received from the upper controller.

In step S602, in a case in which it is determined that the third command is received, the power management device 400 may control power to be supplied from the V2G device to the grid network according to the third command.

In step S602, in a case in which it is determined that the third command is not received, the power management device 400 may return to step S601 and control to maintain the state in which power is not supplied to the grid network from the V2G device.

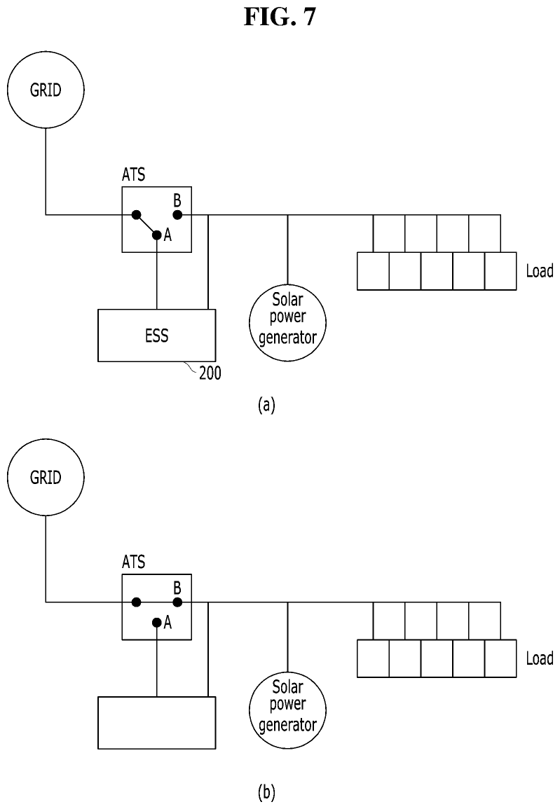

FIG. 7 is a diagram for depicting a process of controlling power supply through an automatic transfer switch (ATS) according to an embodiment.

Referring to FIG. 7, the grid network, a solar power generator, the ESS 200, and a load may be connected through the ATS. Here, the load may include a plurality of low-speed chargers 100, a plurality of high-speed chargers 300, and the V2G device, which are installed in an electric vehicle charging station.

According to an embodiment, the operation of the ATS may be controlled by the power management device 400. the ATS may be connected to a point A as illustrated in FIG. 7A, and may be connected to a point B as illustrated in FIG. 7B.

The power management device 400 may control the ATS to be usually connected to the point A, so as to control power to be supplied from the grid network, the solar power generator, and the ESS 200 to the load.

In the state in which the ATS is connected to the point A, if it is confirmed that the power stored in the ESS 200 or the power produced by a solar power generator is more than the reference value, the power management device 400 may control the power not to be supplied from the grid network to the load but to be supplied to the load only through the solar power generator and the ESS 200.

In the state in which the ATS is connected to the point A, the power management device 400 may control power between the ESS 200 and the electric vehicle to be charged and discharged through the V2G device included in the load.

In a case in which it is confirmed that the power stored in the ESS 200 is less than or equal to the reference value and the frequency of the grid network is higher than the reference value so that the power of the grid network is excessive, the power management device 400 may control the ATS to be connected to the point A so that power is supplied from the grid network to the ESS 200.

In a case in which it is confirmed that the power stored in the ESS 200 is more than or equal to the reference value and the frequency of the grid network is lower than the reference value so that the power of the grid network lacks, the power management device 400 may control the ATS to be connected to the point A so that power stored in the ESS 200 is supplied to the grid network.

That is, the power management device 400 may usually control the ATS to be connected to the point A, and control the power supplied from the grid network to be charged into the ESS 200 when it is determined that power of the ESS 200 lacks. In this instance, the power management device 400 may control the power not to be charged to the ESS 200 if the system frequency is lower than the reference value when the frequency is detected.

That is, in a case in which the power management device 400 monitors the grid network or confirms that power of the grid network is excessive through the command of the upper controller, the power management device 400 may charge power from the grid network. In this case, the electric vehicle charger may be operated at the maximum output, and the V2G device may be blocked.

In the state in which the ATS is connected to the point A, the power management device 400 may control power between the grid network and the electric vehicle to be charged or discharged through the V2G device. In this instance, the grid network, the ESS 200, and the load are connected in order to control supply of power.

Referring to FIG. 7, when the ATS is connected to the point B, the ESS 200 may be separated from the grid network. The separated ESS 200 may move to a place requiring power to serve as a power supplier (power generator) to supply power, and may be used to replace the existing portable diesel generator.

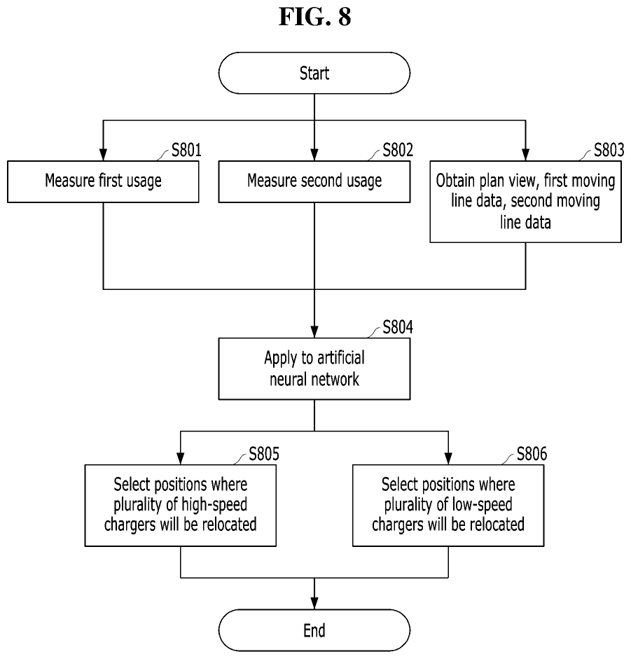

FIG. 8 is a flow chart illustrating a process of selecting relocation positions of the high-speed charger and the low-speed charger according to an embodiment.

First, in step S801, the power management device 400 may measure the first usability for each of the plurality of high-speed chargers 300 arranged in the electric vehicle charging station for a preset period.

For example, the power management device 400 may calculate how many the first high-speed charger 310 provides the high-speed charging service to electric vehicles for one week to measure the first usage of the first high-speed charger 310, and calculate how many the second high-speed charger 320 provides the high-speed charging service to electric vehicles for one week to measure the first usage of the second high-speed charger 320.

In step S802, the power management device 400 may measure the second usability for each of the plurality of low-speed chargers 100 arranged in the electric vehicle charging station for a predetermined period of time.

For example, the power management device 400 may calculate how many the first low-speed charger 110 provides the low-speed charging service to electric vehicles for one week to measure the second usage of the first low-speed charger 110, and calculate how many the second low-speed charger 120 provides the low-speed charging service to electric vehicles for one week to measure the second usage of the second low-speed charger 120.

In step S803, the power management device 400 may obtain a plan view of the electric vehicle charging station, first moving line data of electric vehicles visiting the electric vehicle charging station for high-speed charging for a preset period, and second moving line data of electric vehicles visiting the electric vehicle charging station for low-speed charging for a preset period.

The acquisition of the plan view, the first moving line data, and the second moving line data may be performed by a random access memory (RAM) in a ROM, may be performed by physical insertion of an external device, or may be performed through a wired or wireless network such as the Internet.

The plan view, the first moving line data, the second moving line data, the first usage, and the second usage may be a basis of an input to be applied to the artificial neural network.

In the plan view, the entrance and the exit of the electric vehicle charging station are indicated, and there is no restriction in type, size, format, and the like of the plan view. For example, the plan view may be a CAD file, a vector (SVR) file, an illustration (AI) file, or a TIF file.

A start point and an end point are represented in the first moving line data and the second moving line data, and there is no restriction in type, size, format, and the like of the file.

The power management device 400 may perform preprocessing on the plan view, the first moving line data, the second moving line data to generate an input of the artificial neural network. Specifically, the power management device 400 may perform preprocessing, for instance, to unify forms, to coincide scales, to unify resolution, to leave only the minimum colors required in the color information, and so on.

In addition, the power management device 400 may perform preprocessing of making background areas of the first moving line data and the second moving line data transparent, layering the first moving line data and the second moving line data, and adjusting the entrances and exits of the first moving line data and the second moving line data to coincide with an entrance and an exit of the electric vehicle charging station illustrated on the plan view.

That is, if the plan view includes the entrance and the exit of the electric vehicle charging station and the first moving line data and the second moving line data include a start point and an end point, the start points of the first moving line data and the second moving line data coincide with the entrance of the electric vehicle charging station, and the end points of the first moving line data and the second moving line data may coincide with the exit of the electric vehicle charging station.

In step S804, the power management device 400 may apply the plan view, the first moving line data, the second moving line data, the first usage, and the second usage to the artificial neural network.

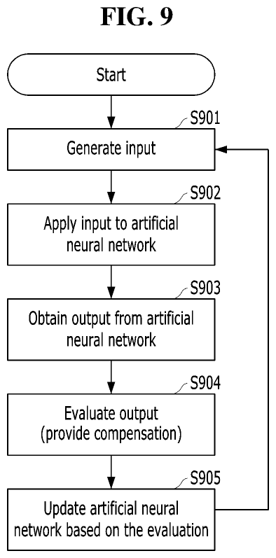

The artificial neural network may be an algorithm that receives the plan view, the first moving line data, the second moving line data, the first usage, and the second usage, and outputs positions where the plurality of high-speed chargers 300 and the plurality of low-speed chargers 100 are relocated along the moving line of the electric vehicles. The artificial neural network may be trained through a method described below with reference to FIG. 9.

In step S805, the power management device 400 may select positions where the plurality of high-speed chargers 300 are respectively relocated based on the output of the artificial neural network.

In step S806, the power management device 400 may select positions where the plurality of low-speed chargers 100 are respectively relocated based on the output of the artificial neural network.

The artificial neural network may be trained to output a location that is capable of reducing the first usage of the high-speed charger that is classified as being used more by exceeding the reference range, and may be trained to output a location that is capable of increasing the first usage of the high-speed charger that is classified as being used less by falling short of the reference range. Accordingly, the artificial neural network may output a position of an area close to the exit of the electric vehicle charging station as a position capable of reducing the first usage, and output a position of an area close to the entrance of the electric vehicle charging station as a position capable of increasing the first usage.

Moreover, the artificial neural network may be trained to output positions of the first high-speed charger 310 and the second high-speed charger 320 such that the plurality of high-speed chargers 300 are positioned at regular intervals from the start point to the end point of the first moving line data. Accordingly, the artificial neural network may output positions where the plurality of high-speed chargers 300 are relocated at regular intervals according to the movement of the electric vehicles.

That is, relocation of each of the plurality of high-speed chargers 300 may be made on the basis of the output of the artificial neural network trained according to reinforcement learning, so that the plurality of high-speed chargers 300 are positioned at regular intervals from the start point to the end point of the first moving line data while changing the position of the high-speed charger for which the first usage is classified as being used more by exceeding the reference range, and the position of the high-speed charger for which the first usage is classified as being used less by falling short of the reference range.

Meanwhile, the artificial neural network may be trained to output a location that is capable of reducing the second usage of the low-speed charger that is classified as being used more by exceeding the reference range, and may be trained to output a location that is capable of increasing the second usage of the low-speed charger that is classified as being used less by falling short of the reference range. Accordingly, the artificial neural network may output a position of an area close to the exit of the electric vehicle charging station as a position capable of reducing the second usage, and output a position of an area close to the entrance of the electric vehicle charging station as a position capable of increasing the second usage.

Moreover, the artificial neural network may be trained to output positions of the first low-speed charger 110 and the second low-speed charger 120 such that the plurality of low-speed chargers 100 are positioned at regular intervals from the start point to the end point of the second moving line data. Accordingly, the artificial neural network may output positions where the plurality of low-speed chargers 100 are relocated at regular intervals according to the movement of the electric vehicles.

That is, relocation of each of the plurality of low-speed chargers 100 may be made on the basis of the output of the artificial neural network trained according to reinforcement learning, so that the plurality of low-speed chargers 100 are positioned at regular intervals from the start point to the end point of the second moving line data while changing the position of the low-speed charger for which the second usage is classified as being used more by exceeding the reference range, and the position of the low-speed charger for which the second usage is classified as being used less by falling short of the reference range.

FIG. 9 is a diagram for depicting training of the artificial neural network according to an embodiment.

The artificial neural network may be an algorithm that receives the plan view, the first moving line data, the second moving line data, the first usage, and the second usage, and outputs positions where the plurality of high-speed chargers 300 and the plurality of low-speed chargers 100 are relocated along the moving line of the electric vehicles. The power management device 400 configured to learn the artificial neural network may be the same device as a device for determining the position where the plurality of high-speed chargers 300 and the plurality of low-speed chargers 100 are relocated by using the trained artificial neural network, or may be a separate device. Hereinafter, a process of training an artificial neural network will be described.

First, in step S901, the power management device 400 may generate an input based on the plan view, the first moving line data, the second moving line data, the first usage, and the second usage of the electric vehicle charging station.

Specifically, the power management device 400 may perform preprocessing, for instance, to unify extension formats of the plan view, an extension format of the first moving line data and the second moving line data, to coincide scales, to unify resolution, to leave only the minimum colors required in the color information, and so on.

In addition, the power management device 400 may perform preprocessing of making background areas of the first moving line data and the second moving line data transparent, layering the first moving line data and the second moving line data, and adjusting the entrances and exits of the first moving line data and the second moving line data to coincide with an entrance and an exit of the electric vehicle charging station illustrated on the plan view.

The preprocessed plan view, first moving line data, second moving line data, first usage, and second usage on which the preprocessing is performed may be used as an input for the artificial neural network as they are, or may be generated as an input after passing through a normal process of removing unnecessary information.

In step S902, the power management device 400 may apply the input to the artificial neural network. The artificial neural network may be an artificial neural network trained according to reinforcement learning. The artificial neural network may be a Q-network, a depp Q-network (DQN), or a relation network (RL) suitable for outputting abstract inference through reinforcement learning.

The artificial neural network trained according to reinforcement learning may be updated and optimized by reflecting evaluation on various compensation. For example, the first compensation may be increased as the positions of the over-used high-speed chargers are rearranged to be close to the end point of the first moving line data in high use order of the first usage, the second compensation may be increased as the positions of the high-speed chargers, which are used less, are rearranged to be close to the starting point of the first moving line data in low use order of the first usage, the third may be increased as the positions of the over-used low-speed chargers are rearranged to be close to the end point of the second moving line data in high use order of the second usage, and the fourth compensation may be increased as the positions of the low-speed chargers, which are used less, are rearranged to be close to the starting point of the second moving line data in low use order of the second usage.

In step of S903, the power management device 400 may obtain an output from the artificial neural network. The output of the artificial neural network may be a position at which each of the plurality of high-speed chargers 300 is relocated and a position in which each of the plurality of low-speed chargers 100 is relocated. At this time, the artificial neural network may determine a location where each of the plurality of high-speed chargers 300 is to be rearranged such that the first usage of the over-used high-speed charger with high first usage is lowered, and the first usage of the high-speed charger, which is used less with low first usage is increased, and determine a location where each of the plurality of low-speed chargers 100 is to be rearranged such that the second usage of the over-used low-speed charger with high second usage is lowered, and the second usage of the low-speed charger, which is used less with low second usage is increased

In step S904, the power management device 400 may evaluate the output of the artificial neural network to provide compensation. The evaluation of the output may be divided into a first compensation, a second compensation, a third compensation, and a fourth compensation.

The power management device 400 may provide more first compensation as the over-used high-speed charger is rearranged to be close to the end of the first moving line data in the high use order of the first usage.

For example, in a case in which the first high-speed charger 310 and the second high-speed charger 320 are classified as the over-used high-speed chargers and the first usage of the first high-speed charger 310 is higher than the first usage of the second high-speed charger 320, the power management device 400 may provide more first compensation as the first high-speed charger 310 among the plurality of high-speed chargers 300 is rearranged closest to the end point of the first moving line data, and may provide more first compensation as the second high-speed charger 320 together with the first high-speed charger 310 is relocated to be close to the end point of the first moving line data.

The power management device 400 may provide more second compensation as the less-used high-speed charger is rearranged to be close to the start point of the first moving line data in the low use order of the first usage.

For example, in a case in which the first high-speed charger 310 and the second high-speed charger 320 are classified as the less-used high-speed chargers and the first usage of the first high-speed charger 310 is lower than the first usage of the second high-speed charger 320, the power management device 400 may provide more second compensation as the first high-speed charger 310 among the plurality of high-speed chargers 300 is rearranged closest to the start point of the first moving line data, and may provide more second compensation as the second high-speed charger 320 together with the first high-speed charger 310 is relocated to be close to the start point of the first moving line data.

The power management device 400 may provide more third compensation as the over-used low-speed charger is rearranged to be close to the end of the second moving line data in the high use order of the second usage.

For example, in a case in which the first low-speed charger 110 and the second low-speed charger 120 are classified as the over-used low-speed chargers and the second usage of the first low-speed charger 110 is higher than the second usage of the second low-speed charger 120, the power management device 400 may provide more third compensation as the first low-speed charger 110 among the plurality of low-speed chargers 100 is rearranged closest to the end point of the second moving line data, and may provide more third compensation as the second low-speed charger 120 together with the first low-speed charger 110 is relocated to be close to the end point of the second moving line data.

The power management device 400 may provide more fourth compensation as the less-used low-speed charger is rearranged to be close to the start point of the second moving line data in the low use order of the second usage.

For example, in a case in which the first low-speed charger 110 and the second low-speed charger 320 are classified as the less-used low-speed chargers and the second usage of the first low-speed charger 110 is lower than the second usage of the second low-speed charger 320, the power management device 400 may provide more fourth compensation as the first low-speed charger 110 among the plurality of low-speed chargers 100 is rearranged closest to the start point of the second moving line data, and may provide more fourth compensation as the second low-speed charger 120 together with the first low-speed charger 110 is relocated to be close to the start point of the second moving line data.

In step S905, the power management device 400 may update the artificial neural network based on the evaluation. In detail, the power management device 400 may update the artificial neural network through a process of optimizing a policy for determining actions to be taken in specific states to maximize expectation of the sum of rewards (compensation values) in an environment in which the artificial neural network relocates the plurality of high-speed chargers 300 having the first usage and relocates the plurality of low-speed chargers 100 having the second usage, along the moving line data of the electric vehicles on the plan view of the electric vehicle charging station.

Meanwhile, the process of optimizing the policy may be performed through a process of estimating the maximum value of the expected value of the sum of the rewards or the maximum value of the Q-function, or estimating the minimum value of the loss function of the Q-function. The estimation of the minimum value of the loss function may be performed through stochastic gradient descent (SGD) or the like. The process of optimizing the policy is not limited thereto, and various optimization algorithms used in reinforcement learning may be used.

The power management device 400 may gradually update the artificial neural network by repeating the learning process of the artificial neural network as described above. Accordingly, the power management device 400 may train the artificial neural network for outputting the positions where the plurality of high-speed chargers 300 and the plurality of low-speed chargers 100 are relocated, in accordance with the purpose of rearranging the positions according to the usage of the chargers.

Specifically, when the first compensation, the second compensation, the third compensation, and the fourth compensation have the same compensation system, in a case in which the first compensation, the second compensation, the third compensation, and the fourth compensation correspond to the same compensation system, if the rewards given as the first compensation and the second compensation is the same as the rewards given as the third compensation and the fourth compensation, the artificial neural network may be updated to increase the first compensation, the second compensation, the third compensation, and the fourth compensation to be the same so that the expectation of the sum of the reward values is maximized.

Accordingly, considering that relocation of the plurality of high-speed chargers 300 according to the first usage and relocation of the plurality of low-speed chargers 100 according to the second usage are in the same importance, the artificial neural network may output positions where the plurality of high-speed chargers 300 and the plurality of low-speed chargers 100 will be relocated.

The embodiments described above may be implemented as hardware components, software components, and/or a combination of hardware and software components. For example, the devices, methods, and components described in the embodiments may be implemented using one or more general-purpose computers or special-purpose computers, such as processors, controllers, arithmetic logic units (ALUs), digital signal processors (DSPs), microcomputers, field programmable gate arrays (FPGAs), programmable logic units (PLUs), microprocessors, or other devices capable of executing instructions and responding. The processing device may be implemented using one or more general-purpose computers or special-purpose computers to execute one or more software applications on an operating system (OS) and respond to the execution of the software by accessing, storing, manipulating, processing, and generating data. For convenience of understanding, the processing device may be described as using one processing element, but those skilled in the art would understand that the processing device may include multiple processing elements and/or multiple types of processing elements. For example, the processing device may include multiple processors or one processor and one controller. Additionally, other processing configurations, such as parallel processors, are also possible in the field of the technology with common knowledge.

The method according to an embodiment can be implemented in the form of program instructions that can be executed through various computer means and recorded on a computer-readable medium. The computer-readable medium may include program instructions, data files, data structures, or a combination thereof. The program instructions recorded on the medium may be specially designed and configured for the embodiments, or may be publicly available to computer software practitioners. Examples of computer-readable recording media include magnetic media such as hard disks, floppy disks, and magnetic tapes; optical media such as CD-ROMs and DVDs; magneto-optical media such as floptical disks; and hardware devices specifically configured to store and execute program instructions, such as ROM, RAM, and flash memory. Examples of program instructions include machine language code created by a compiler, as well as high-level language code that can be executed by a computer using an interpreter or the like. The aforementioned hardware devices can be configured to operate as one or more software modules to perform the operations of the embodiments, and vice versa.

Software may include one or more of a computer program, code, instruction, or a combination thereof, and may configure a processing device to operate as desired or independently or collectively command the processing device. Software and/or data may be permanently or temporarily embodied in any type of machine, component, physical device, virtual device, computer storage medium or device, or signal wave transmitted for interpretation or provision of commands or data to a processing device. Software and data may be distributed on a networked computer system and stored or executed in a distributed manner. Software and data may be stored on one or more computer-readable recording media.

Although the embodiments have been described with reference to limited drawings, those skilled in the art will appreciate that various modifications and variations can be applied based on common knowledge in the technical field. For example, the described techniques may be performed in a different order than described, and/or components of the described systems, structures, devices, circuits, or the like may be combined or assembled in different forms, or replaced or substituted with other components or equivalents, and still achieve the desired results.

Therefore, various implementations, modifications, and variations may be made to the embodiments without departing from the scope of the invention, as defined by the claims.

1. A method for managing power of an electric vehicle charging station using an energy storage system (ESS) in a power management device, comprising the steps of:
measuring the charging amount of the ESS by checking the state of charge (SOC) of the ESS;
determining whether the charging amount of the ESS is less than a first set value set through the emergency storage capacity of the ESS;
if it is determined that the charging amount of the ESS is greater than the first set value, setting the ESS to a discharge mode, and controlling the ESS to enable high-speed charging through a plurality of high-speed chargers connected to the ESS by providing power to the plurality of high-speed chargers;
if it is determined that the charging amount of the ESS is less than the first set value, setting the ESS to a charge mode, and controlling the ESS to stop the operation of the plurality of high-speed chargers by not supplying power to the plurality of high-speed chargers;
in a case in which the ESS is set to the discharge mode, simultaneously operating the high-speed chargers that exceed a reference value, among the plurality of high-speed chargers, and checking the charging state of the ESS again when the discharging amount of the ESS reaches a target value; and
in a case in which the ESS is set to the charge mode, checking the charging state of the ESS again if the charge mode of the ESS is maintained for a predetermined reference period.

2. The method according to claim 1, further comprising the steps of:
if it is determined that the charging amount of the ESS is less than the first set value, determining whether there is a high-speed charger in operation which provides a high-speed charge service, among the plurality of high-speed chargers;
if it is determined that there is no high-speed charger in operation, setting the ESS to the charge mode, and controlling to stop the operation of the plurality of high-speed chargers;
if it is determined that there is a high-speed charger in operation, determining whether the charging amount of the ESS is less than the second set value based on the state of health (SOH) of the ESS;
if it is determined that the charging amount of the ESS is greater than the second set value, controlling to supply power to the high-speed charger in operation to continue high-speed charging through the high-speed charger in operation;
if the high-speed charging through the high-speed charger in operation is continued, when the high-speed charging is completed, setting the ESS to the charging mode and controlling to stop the operation of the high-speed charger in operation; and
if it is determined that the charging amount of the ESS is less than the second set value, setting the ESS to the charging mode and controlling to stop the operation of the high-speed charger in operation even if high-speed charging through the high-speed charger in operation is not completed.

3. The method according to claim 1, further comprising the steps of:
if the frequency of a grid network exceeds a predetermined reference value, receiving a first command from an upper controller that manages a plurality of power management devices arranged in different regions, and setting the ESS to the charging mode according to the first command;
if the frequency of a grid network is lower than the reference value, receiving a second command from an upper controller, and setting the ESS to the discharging mode according to the second command;
detecting the frequency of a distribution network connected to the ESS, and if it is determined that the frequency of the distribution network is higher than a reference range, setting the ESS to the charging mode, and if it is determined that the frequency of the distribution network is lower than a reference range, setting the ESS to the discharging mode;
if the ESS is connected to a vehicle to grid (V2G) device, controlling power not to be supplied from the V2G device to the grid network, and controlling the power supplied from the V2G device to be first stored in the ESS or to be used as power consumption in a charging station; and
when a third command is received from the upper controller, controlling power to be supplied from the V2G device to the grid network according to the third command.
